(19) United States
(12) Patent Application Publication
(10) Pub. No.: US 2012/0175790 A1
(43) Pub. Date: Jul. 12, 2012

(54) COMPOSITION FOR PATTERNABLE ADHESIVE FILM, PATTERNABLE ADHESIVE FILM, AND METHOD OF MANUFACTURING SEMICONDUCTOR PACKAGE USING THE SAME

(75) Inventors: Yong Seok HAN, Anyang-si (KR); Joon Yong PARK, Suwon-si (KR); Jae Jun LEE, Suwon-si (KR); Chul Ho JEONG, Gwangju (KR)

(73) Assignee: SAMSUNG ELECTRONICS CO., LTD., Suwon-si (KR)

(21) Appl. No.: 13/198,811

(22) Filed: Aug. 5, 2011

(30) Foreign Application Priority Data
Jan. 7, 2011 (KR) 10-2011-0001806

(51) Int. Cl. C08L 33/08; H01L 21/02; H01L 23/00

(52) U.S. Cl. 257/798; 522/42; 438/758; 257/E23.001; 257/E21.002

(57) ABSTRACT

A composition for a patternable adhesive film, a patternable adhesive film having the same, and a method of manufacturing a semiconductor package using the patternable adhesive film are provided. The composition contains a binder resin, a radical-polymerizable acrylate monomer, a photo-radical initiator, and a thermal-radical initiator without an epoxy resin. The composition may have good patternability, adhesiveness, and low-temperature stability, and be rapidly cured at a low temperature.

### CROSS-REFERENCE TO RELATED APPLICATION

This application claims priority to of Korean Patent Application No. 10-2011-0001806, filed on Jan. 7, 2011, and all the benefits accruing therefrom under 35 U.S.C. §119, the content of which in its entirety is herein incorporated by reference.

### BACKGROUND

1. Field

This disclosure relates to a composition for a patternable adhesive film, a patternable adhesive film, a semiconductor package formed using the composition or the patternable adhesive film, and a method of manufacturing the semiconductor package.

2. Description of the Related Art

In recent years, various semiconductor packages have been developed to provide improved semiconductor device integration and capacity. In a semiconductor package, an adhesive film is used to adhere a semiconductor device to a supportive substrate.

The adhesive film has excellent thickness and protrusion control capacity when compared to a commercially available paste adhesive. Accordingly, the adhesive film is widely used in high-density semiconductor packages, such as a chip-size package, a stack package, or a system-in package.

To mount a semiconductor device in a semiconductor package using an adhesive film, the patternable adhesive film desirably has excellent adhesiveness and patternability, fast curing properties at a low temperature, and sufficient storage stability.

### SUMMARY

Disclosed is a composition for a patternable adhesive film which may have excellent adhesiveness and patternability, and fast curing properties at a low temperature. Also disclosed is an adhesive film, a semiconductor package manufactured using the composition or the adhesive film, and a method of manufacturing the semiconductor package.

In an aspect, a composition for a patternable adhesive film includes a binder resin, a radical-polymerizable acrylate monomer, a photo-radical initiator, a thermal-radical initiator, and a solvent.

In another aspect, a patternable adhesive film, which includes a product prepared by removing a solvent from the composition, is provided.

In another aspect, a semiconductor package includes a plurality of semiconductor chips; and an adhesive layer, wherein the adhesive layer is a product of curing or removing a solvent from the composition.

In another aspect, disclosed is a method of manufacturing a semiconductor package, the method including: applying a composition on a surface of a semiconductor chip or on a surface of a substrate to form a patternable adhesive film, wherein the composition includes a binder resin, a radical-polymerizable acrylate monomer, a photo-radical initiator, a thermal radical initiator, and a solvent; forming a predetermined pattern by exposing and developing the patternable adhesive film, and forming an adhesive layer by a thermally curing the patternable adhesive film to form the semiconductor package.

Also disclosed is a method of manufacturing a semiconductor package, the method including: disposing a patternable adhesive film, wherein the adhesive film is prepared by removing a solvent from a composition including a binder resin, a radical-polymerizable acrylate monomer, a photo-radical initiator, a thermal radical initiator, and a solvent; forming a predetermined pattern by exposing and developing the patternable adhesive film; and forming an adhesive layer by a thermally curing the patternable adhesive film to form the semiconductor package.

The composition for the patternable adhesive film may include a binder resin, a radical-polymerizable acrylate monomer, a photo-radical initiator, a thermal radical initiator, and a solvent.

The patternable adhesive film may be formed using the composition.

The semiconductor package and the method of manufacturing the same may use the composition or the patternable adhesive film.

### BRIEF DESCRIPTION OF THE DRAWINGS

The above and other aspects, advantages and features of this invention will become more apparent by describing in further detail exemplary embodiments thereof with reference to the accompanying drawings, in which:

FIG. 1 is a scanning electronic micrograph (“SEM”) of a pattern according to Example 1, which is taken according to Experimental Example 1;

FIG. 2 is a SEM of a pattern according to Comparative Example 1, which is taken according to Experimental Example 1; and

FIG. 3 is a SEM of a pattern according to Comparative Example 2, which is taken according to Experimental Example 1.

### DETAILED DESCRIPTION

The invention now will be described more fully hereinafter with reference to the accompanying drawings, in which a non-limiting embodiment is shown. This invention may, however, be embodied in many different forms, and should not be construed as limited to the example embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers, and/or sections, these elements, components, regions, layers, and/or sections should not be limited by these terms. These terms are only used to distinguish one element, component, region, layer, or section from another element, component, region, layer, or section. Thus, a first element, component, region, layer, or section discussed below could be termed a second element, component, region, layer, or section without departing from the teachings of the invention.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” or “includes” and/or “including” when used in this specification, specify the presence of stated regions, integers, steps, operations, elements, and/or components, but do not preclude the presence or addition of one or more other regions, integers, steps, operations, elements, components, and/or groups thereof.

Furthermore, relative terms, such as “lower” or “bottom” and “upper” or “top,” may be used herein to describe one element's relationship to another element as illustrated in the figures. It will be understood that relative terms are intended to encompass different orientations of the device in addition to the orientation depicted in the figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

One or more embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear portions. Moreover, sharp angles that are illustrated may be rounded. Thus, the regions illustrated in the figures are schematic in nature and their shapes are not intended to illustrate the precise shape of a region and are not intended to limit the scope of the claims.

In an aspect, disclosed is a composition for a patternable adhesive film, the composition comprising a binder resin, a radical-polymerizable acrylate monomer, a photo-radical initiator, a thermal-radical initiator, and a solvent. In an embodiment the solvent may be an organic solvent.

The composition for the patternable adhesive film may not include an epoxy resin as a thermal-curing compound. Thus in an embodiment neither the binder resin nor the radical-polymerizable acrylate monomer comprises an epoxy resin. In an embodiment, none of the binder resin, the radical-polymerizable acrylate monomer, the photo-radical initiator, the thermal-radical initiator, nor the solvent comprises an epoxy resin. The composition for the patternable adhesive film may include the thermal-radical initiator instead of an epoxy resin that may be present in a commercially available composition, thus the radical-polymerizable acrylate monomer may be photo-curable and may also be thermally curable. Since the composition for the patternable adhesive film does not include the epoxy resin, the patternability of the adhesive film may be improved, and the adhesiveness of the patternable adhesive film, which while not wanting to be bound by theory, is believed to be adversely affected by elution of the epoxy resin, may not be reduced during a developing processes. Also, a storage stability of the composition may be increased by blocking or avoiding a reaction of the epoxy resin with a carboxylic group, which may be included in the composition as a developing component.

### Binder Resin

A binder resin may serve as a matrix for a patternable adhesive film. The binder resin may comprise at least one selected from an oligomer and a polymer, each of which may independently comprise a double bond, which may provide light curing properties, and may further optionally comprise a carboxylic group, a hydroxyl group, or phenolic group, which may provide desirable alkali developing properties.

For example, the binder resin may be at least one selected from a (meth)acrylate resin comprising at least one (meth)acryloyl group, an unsaturated polyester diarylphthalate resin, a vinyl ester resin, and a bismaleimide resin. For example, the binder resin may be at least one selected from methyl(meth)acrylate, ethyl(meth)acrylate, butyl(meth)acrylate, isobutyl(meth)acrylate, 2-ethylhexyl(meth)acrylate, isooctyl(meth)acrylate, glycidyl(meth)acrylate, cyclohexyl(meth)acrylate, isobornyl(meth)acrylate, benzyl(meth)acrylate, 2-hydroxy(meth)acrylate, trimethoxybutyl(meth)acrylate, ethylcarbitol(meth)acrylate, phenoxyethyl(meth)acrylate, 2-hydroxyethyl(meth)acrylate, trimethylolpropane tri(meth)acrylate, tetramethylolmethane tetra(meth)acrylate, pentaerythritol hexa(meth)acrylate, pentaerythritol tetra(meth)acrylate, dipentadierythritolmonohydroxy penta(meth)acrylate, dipentaerythritol hexa(meth)acrylate, 1,4-butylglycol di(meth)acrylate, 1,6-hexanediol di(meth)acrylate, polyethyleneglycol di(meth)acrylate, oligoester (meth)acrylate, a multifunctional urethane (meth)acrylate, and urea (meth)acrylate.

A content of the binder resin may be in a range of about 5 to about 50 percent (%) by weight, or about 10 to about 40% by weight, or about 15 to about 35% by weight, based on the total weight of the binder resin, the radical-polymerizable acrylate monomer, the photo-radical initiator, and the thermal radical initiator. Within the above range, the adhesive film may be properly formed, and substantially no un-reacted binder resin may remain. While not wanting to be bound by theory, it is understood that the substantially or essentially complete use (e.g., reaction) of the binder resin substantially or effectively prevents degradation of the physical properties of the adhesive film.

### Radical-Polymerizable Acrylate Monomer

The radical-polymerizable acrylate monomer is not especially limited, so long as the radical-polymerizable acrylate monomer has a functional group including an ethylenic double bond which enables (e.g., participates in) a curing reaction promoted by a photo-radical initiator and/or a thermal-radical initiator. The radical-polymerizable acrylate monomer may be an acrylate-based monomer comprising an acryloyl group.

The radical-polymerizable acrylate monomer may include an acryloyl group which may enable (e.g., participate in) a curing reaction, and may optionally further include a carboxylic group, a hydroxyl group, or a phenolic group, which may provide desirable alkali developing properties.

As above, the composition for the patternable adhesive film may not include an epoxy resin as a thermosetting compound, and thus the radical-polymerizable acrylate monomer may be thermally curable.

In an embodiment, about 60 to about 90% by weight, or about 70 to about 80% by weight, or about 75% by weight of the radical-polymerizable acrylate monomer, based on the total weight of the radical-polymerizable acrylate monomer, may be cured by the photo-radical initiator, and about 40 to about 10%, or about 30 to about 20% by weight, or about 25% by weight of the radical-polymerizable acrylate monomer, based on the total weight of the radical-polymerizable acrylate monomer, may be cured by the thermal radical initiator. Thus, the content, weight-average molecular weight, and reaction rate of the photo-radical initiator and the thermal radical initiator with respect to the radical-polymerizable acrylate monomer may be appropriately selected.

For example, the radical polymer acrylate monomer may comprise at least one selected from isobornyl(meth)acrylate, 1,6-hexanediol diacrylate, triethylene glycol diacrylate, trimethylolpropane triacrylate, tetraethylene glycol diacrylate, 1,3-butanediol diacrylate, neopentyl glycol diacrylate, pentaerythritol triacrylate, and dipentaerythritol hydroxypentacrylate.

A weight-average molecular weight (“MW”) of the radical-polymerizable acrylate monomer may in the range of about 100 to about 20,000 grams per mole (g/mol), or about 200 to about 10,000 g/mol, or about 300 to about 5,000 g/mol. Within the above range, curing speed (e.g., a curing rate) may be controlled so that the radical-polymerizable acrylate monomer cannot be completely cured by the photo-radical initiator, but may remain partially unreacted and subsequently cured by the thermal-radical initiator.

A content of the radical-polymerizable acrylate monomer may be in the range of about 10 to about 80% by weight, or about 20 to about 70% by weight, or about 30 to about 60% by weight, based on the total weight of the binder resin, the radical-polymerizable acrylate monomer, the photo-radical initiator, and the thermal radical initiator. Within the above range, the radical-polymerizable acrylate monomer may not be completely cured by the photo-radical initiator but a portion may be subsequently cured by the thermal-radical initiator. For example, the content of the radical-polymerizable acrylate monomer may be from about 30 to about 60% by weight, based on the total weight of the binder resin, the radical-polymerizable acrylate monomer, the photo-radical initiator, and the thermal radical initiator.

### Photo-Radical Initiator

The photo-radical initiator may cure a portion of the radical-polymerizable acrylate monomer, for example, about 60 to about 90% by weight, or about 70 to about 80% by weight, or about 75% by weight of the radical-polymerizable acrylate monomer, based on the total weight of the radical-polymerizable acrylate monomer, upon exposure to light, such as ultraviolet (“UV”) light.

The photo-radical initiator may have a 400-nm absorption band and may provide a highly precise pattern as a result of a UV exposure process. For example, the photo-radical initiator may include, but is not limited to, at least one selected from 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, methyl benzoylformate, α,α-dimethoxy-α-phenylacetophenone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diphenyl (2,4,6-trimethylbenzoyl)-phosphine oxide, and phosphine oxide.

A content of the photo-radical initiator may be in the range of about 0.1 to about 5% by weight, or about 0.2 to about 4% by weight, or about 0.4 to about 3% by weight, based on the total weight of the binder resin, the radical-polymerizable acrylate monomer, the photo-radical initiator, and the thermal radical initiator. Within the above range, the radical-polymerizable acrylate monomer may not be completely cured by the photo-radical initiator and a portion may remain and that portion may be subsequently cured by the thermal-radical initiator. For example, the content of the photo-radical initiator may be from about 0.5 to about 2% by weight, based on the total weight of the binder resin, the radical-polymerizable acrylate monomer, the photo-radical initiator, and the thermal radical initiator.

A ratio of the content of the radical-polymerizable acrylate monomer to the content of the photo-radical initiator may affect the extent of curing of the radical-polymerizable acrylate monomer. To perform a subsequent curing reaction by the thermal-radical initiator, an extent of the reactions initiated by the photo-radical initiator and the radical-polymerizable acrylate monomer are desirably each individually controlled. The extent of the reaction of the radical-polymerizable acrylate monomer initiated by the photo-radical initiator may be controlled using a reaction rate of the photo-radical initiator. For example, a weight ratio of the photo-radical initiator to the radical-polymerizable acrylate monomer may be in the range of about 0.01:1 to about 0.5:1, or about 0.02:1 to about 0.4:1, or about 0.04:1 to about 0.3:1.

### Thermal-Radical Initiator

The thermal-radical initiator may cure an uncured portion of the radical-polymerizable acrylate monomer, wherein the uncured portion is a portion which is not cured by the photo-radical initiator. The thermal-radical initiator may cure the radical-polymerizable acrylate monomer in a thermal compression bonding process. A thermal polymerization initiation temperature of the thermal-radical initiator may be in the range of about 80 to about 150° C., or about 90 to about 140° C., or about 100 to about 130° C.

The thermal-radical initiator may include at least one selected from an organic peroxide, and an organic nitrate compound, but is not limited thereto. For example, the thermal-radical initiator may include at least one selected from a ketone peroxide comprising methyl isobutyl ketone, a hydroperoxide comprising tertiary butyl hydroperoxide, peroxyester, dialkyl peroxide, methoxybutyl peroxydicarbonate, di-(2,4-dichlorobenzoyl)-peroxide, dibenzoyl peroxide, t-butyl peroxybenzoate, 1,1-di-(t-butylperoxy)-3,3,5-trimethylcyclohexane, dicumyl peroxide, di-(2-t-butylperoxyisopropyl)benzene, t-butylcumylperoxide, di-t-butylperoxide, azobisisobutyronitrile, azobiscarbonamide, and azobisalkanonitrile.

A content of the thermal-radical initiator may be in the range of about 0.1 to about 5% by weight, or about 0.2 to about 4% by weight, or about 0.4 to about 3% by weight, based on the total weight of the binder resin, the radical-polymerizable acrylate monomer, the photo-radical initiator, and the thermal radical initiator. Within the above range, after the radical-polymerizable acrylate monomer is photo-cured by the photo-radical initiator, the thermal-radical initiator may sufficiently cure the unreacted (e.g., uncured) portion of the radical-polymerizable acrylate monomer, thereby enabling a rapid curing process. For example, the content of the thermal-radical initiator may be from about 0.5 to about 2% by weight, or about 0.6 to about 1.8% by weight, or about 0.7 to about 1.6% by weight, based on the total weight of the binder resin, the radical-polymerizable acrylate monomer, the photo-radical initiator, and the thermal radical initiator.

### Solvent

The solvent may comprise an organic solvent and may be appropriately selected and used to uniformly dissolve or disperse solid components of the composition for the patternable adhesive film. For example, the organic solvent may comprise at least one selected from dimethyl formamide, dimethyl sulfoxide, toluene, benzene, xylene, methyl ethyl ketone, tetrahydrofuran, ethyl acetate, ethyl cellosolve, ethyl cellosolve acetate, dioxane, cyclohexanone, and N-methyl-pyrrolidinone. The organic solvent may be used alone or in a combination thereof.

The content of the solvent is not especially limited, and the solvent may be added at (e.g., included in) an amount of about 10 to about 80% by weight, or about 20 to about 70% by weight, or about 30 to about 60% by weight, based on the total weight of the composition for the patternable adhesive film.

In addition to the binder resin, the radical-polymerizable acrylate monomer, the photo-radical initiator, the thermal-radical initiator, and the solvent, the composition for the patternable adhesive film may further include a silane coupling agent. While not wanting to be bound by theory, it is understood that the silane coupling agent may increase the adhesiveness of the composition for the patternable adhesive film.

The silane coupling agent may include, but is not limited thereto, at least one selected from vinyltrimethoxysilane, vinyltriethoxysilane, (meth)acryloxypropyltrimethoxysilane, 3-glycidoxypropyltrimethoxysilane, 3-glycidoxypropylmethyldimethoxysilane, and 2-(3,4-epoxycyclohexyl)ethyltrimethoxysilane. A content of the silane coupling agent may be in the range of about 0.1 to about 5% by weight, or about 0.2 to about 4% by weight, or about 0.4 to about 3% by weight, based on the total weight of the binder resin, the radical-polymerizable acrylate monomer, the photo-radical initiator, and the thermal radical initiator. Within the above range, the adhesiveness of the final adhesive film may be improved, and the physical properties thereof may not be degraded.

The composition for the patternable adhesive film may further include at least one additive selected from an organic filler and an inorganic filler. For example, the additive may include, but is not limited to, an inorganic filler, such as at least one selected from silica, alumina, boron nitride, titanium dioxide, glass, iron oxide, boron aluminum, ceramic, and a rubber filler. A content of the additive may be in the range of about 0.1 to about 5 parts by weight, or about 0.2 to about 4% by weight, or about 0.4 to about 3% by weight, based on 100 parts by weight of the composition for the patternable adhesive film.

The composition for the patternable adhesive film may be cured at a temperature of about 250° C. within about 10 seconds, for example, within about 3 to about 7 seconds. In an embodiment, the composition for the patternable adhesive film is cured in about 1 to about 10 seconds, or about 2 to about 9 seconds, or about 3 to about 8 seconds, when treated at 250° C.

In another aspect, a patternable adhesive film may be formed using the composition.

A base film of the patternable adhesive film may include, but is not limited thereto, polyethyleneterephthalate (“PET”).

The patternable adhesive film may be prepared by a suitable method, which can be selected by one of ordinary skill in the art without undue experimentation. For example, the patternable adhesive film may be prepared by applying the composition onto a substrate to form a layer comprising an appropriate thickness using a base film roll coater or bar coater, and removing the solvent to form the patternable adhesive film. The patternable adhesive film may optionally be thermally compressed onto an upper protective film. Since the patternable adhesive film has suitable adhesiveness, suitable patternability, and suitable heat resistance, the patternable adhesive film may be used to provide a semiconductor package.

In another aspect, a semiconductor package manufactured using the composition or the adhesive film and a method of manufacturing the same are provided.

For instance, the semiconductor package may be manufactured by applying the composition onto a semiconductor chip or a base material, or by bonding (e.g., adhering) the adhesive film to a semiconductor chip with the composition.

The base material may comprise a silicon wafer and a plastic or ceramic circuit board, is not limited thereto.

In an embodiment, the semiconductor package may comprise a plurality of semiconductor chips; and an adhesive layer disposed between adjacent semiconductor chips. The adhesive layer may be formed by curing the composition or the adhesive film.

In an embodiment, a method of manufacturing a semiconductor package comprises: (a) applying the composition or disposing the adhesive film onto a surface of a semiconductor chip or onto a surface of a substrate; (b) forming a predetermined pattern by exposing and developing the composition or the adhesive film; and (c) forming an adhesive layer by thermally curing the exposed and developed composition or adhesive film to form the semiconductor package. The composition may comprise the binder resin, the radical-polymerizable acrylate monomer, the photo-radical initiator, the thermal radical initiator, and the solvent. The exposing may comprise ultraviolet (“UV”) exposure.

In an embodiment, the method of manufacturing the semiconductor package comprise: applying the composition on a surface of a semiconductor chip or on the surface of a substrate to form a patternable adhesive film, wherein the composition comprises the binder resin, the radical-polymerizable acrylate monomer, the photo-radical initiator, the thermal radical initiator, and the solvent; forming the predetermined pattern by exposing and developing the patternable adhesive film; and forming the adhesive layer by a thermally curing the patternable adhesive film to form the semiconductor package.

In another embodiment, the method of manufacturing the semiconductor package comprises disposing the adhesive film, wherein the adhesive film is prepared by removing the solvent from the composition comprising the binder resin, the radical-polymerizable acrylate monomer, the photo-radical initiator, the thermal radical initiator, and the solvent; forming a predetermined pattern by exposing and developing the patternable adhesive film; and forming the adhesive layer by thermally curing the patternable adhesive film to form the semiconductor package.

In the applying of the composition or the disposing of the adhesive film (a), a method of applying the composition may comprise at least one selected from a dipping process, a spin coating process, and a roll coating process, but is not limited thereto. Also, an amount of the applied composition may be appropriately selected according to the intended purpose without undue experimentation, and the composition may be applied to provide a layer of the composition having a thickness of about 0.1 to about 100 micrometers (μm), or 0.2 to about 90 μm, or 0.4 to about 80 μm. In an embodiment, the applying of the composition (a) may be followed by volatilizing a solvent of the composition. For example, the solvent may be volatilized at about of 30 to about 150° C., or about of 40 to about 140° C., or about of 50 to about 130° C., for about 1 minute to about 2 hours, or about 10 minutes to about 1.8 hours, or about 20 minutes to about 1.6 hours.

In the forming a predetermined pattern by exposing and developing the composition or the adhesive film (b), the exposure process may include exposing the composition or the adhesive film using UV light through a photomask at an exposure dose of about 10 to about 2000 mJ/cm², or about 20 to about 1800 mJ/cm², or about 40 to about 1600 mJ/cm². The exposure process may be followed by heat treating to increase a developing sensitivity, if desired.

The exposure and/or heating processes may be followed by a developing process using a developing solution. The developing solution may comprise a commercially available organic solvent, such as dimethylacetamide or cyclohexanone. The developing process may be performed by any suitable method, for example dipping a patterned material, as can be determined without undue experimentation. The developing process may be followed by an additional cleaning or drying process, when desired.

In the forming of the adhesive layer by thermally curing the exposed and developed adhesive composition or adhesive film (c), the thermal curing process may be performed at a temperature of about 120 to about 300° C., or about 130 to about 290° C., or about 140 to about 280° C., for about 10 minutes to about 10 hours, or about 20 minutes to about 8 hours, or about 40 minutes to about 6 hours. Due to the thermal curing process, a crosslinking density may increase and the remaining volatile components may be substantially or effectively removed. While not wanting to be bound by theory, it is believed that because of the increased crosslinking density and removal of the volatile components, the composition provides improved adhesiveness to the base material, and improved heat resistance and strength.

The applying of the composition or the disposing of the adhesive film (a), and the forming a predetermined pattern by exposing and developing the composition or the adhesive film (b) may be repeated according to the number of semiconductor chips in the semiconductor package, and the forming of an adhesive layer by thermally curing the exposed and developed composition or adhesive film (c) may be always performed after the applying of the composition or the disposing of the adhesive film (a) and the forming a predetermined pattern by exposing and developing the composition or the adhesive film (b), or performed only once as a final step.

In addition, when the method of manufacturing a semiconductor package includes adhering the semiconductor chips to each other, a first semiconductor chip may be mounted on a patterned adhesive pattern after the forming a predetermined pattern by exposing and developing the composition or the adhesive film (b), followed by the forming an adhesive layer by thermally curing the exposed and developed composition or adhesive film (c).

Hereinafter, the exemplary embodiments will be disclosed in further detail with reference to following Examples. The following examples are merely to explain the exemplary embodiments, and shall not limit the disclosed embodiments.

A detailed specification of components used in the following Examples and Comparative Examples is as follows:

1) Binder resin: ACA-230AA (Daicel Chemical) is an acrylic binder resin, which is an acryl copolymer resin.
2) Radical-polymerizable acrylate monomer: UXE-3000 and UXE-5002D (Nippon Kayaku) are multifunctional acrylates.
3) Photo-radical initiator: Irgagure-369 (Ciba Speciality Chemical) comprises 1-hydroxy-cyclohexyl-phenyl-ketone.
4) Thermal-radical initiator: Luperox 101 (Arkema) comprises 2,5-bis(t-butylperoxy)-2,5-dimethylhexane.
5) Organic solvent: cyclohexanone is used.
6) Silane coupling agent: 3-(trimethoxysilyl)propyl methacrylate is used.
7) Epoxy resin: EOCN-1045 (Nippon Kayaku) and YDCN-500-90P (Kukdo Chemical) are cresol novolac epoxies.
8) Phenol resin: HF-1M (Meiwa) is a novolac-type phenol.
9) 2E4MZ (Shikoku chemical), comprises 2-ethyl-4-methyl imidazole, is used as a curing catalyst, and CGI1380 (Specialty Chemical) is used as a photo-acid generator.

### Examples 1 and 2

The above solid components, i.e., the photo-radical initiator, the thermal-radical initiator, the silane coupling agent, the epoxy resin, the phenol resin, and the photo-acid generator, are added to cyclohexanone solvent in the respective amounts disclosed in Table 1, and mixed with a planetary mixer at a rotary rate of about 1000 revolutions per minute (“rpm”) for about 10 minutes. The obtained composition is applied onto a PET film whose surface is treated with silicone with a comma coater or a lip coater, and dried at a temperature of about 85° C. for about 10 minutes to prepare a 20 μm-thick patternable adhesive film.

### Comparative Examples 1 and 2

Patternable adhesive films are prepared by the same method as in Examples 1 and 2, except that the compositions and contents corresponding to Comparative Examples 1 and 2 shown in Table 1 are used.

TABLE 1

| | | | | Compar- | Compar- |
|---|---|---|---|---|---|
| | | Exam- | Exam- | ative | ative |
| | | ple 1 | ple 2 | Example 1 | Example 2 |
| Binder resin | | 32.6 | 32.6 | 32.6 | 19.1 |
| Radical- | UXE-3000 | 32.6 | 32.6 | 32.6 | 19.1 |
| polymerizable | UXE-3000 | 32.6 | 32.6 | 32.6 | 19.1 |
| monomer | | | | | |
| [symbol] | [symbol] | 1.1 | 1.1 | 2.2 | 1.4 |
| [symbol] | [symbol] | [symbol] | [symbol] | [symbol] | [symbol] |
| monomer | EOCN-104S | — | — | — | 19.1 |
| | YDCN- | — | — | — | 19.1 |
| | 500-90P | | | | |

| | | | | |
|---|---|---|---|---|
| Phenol resin | — | — | — | 9.5 |
| Catalyst | — | — | — | 0.2 |
| Coupling agent | — | 1 | 1 | 1.0 |
| Photo-acid generator | — | — | — | 0.6 |

[symbol]

indicates data missing or illegible when filed

In Table 1, the values are percent (%) by weight, based on the total weight of the photo-radical initiator, the thermal-radical initiator, the silane coupling agent, the epoxy resin, the phenol resin, and the photo-acid generator.

### Experimental Example

### Measurement of Physical Properties of Patternable Adhesive Film

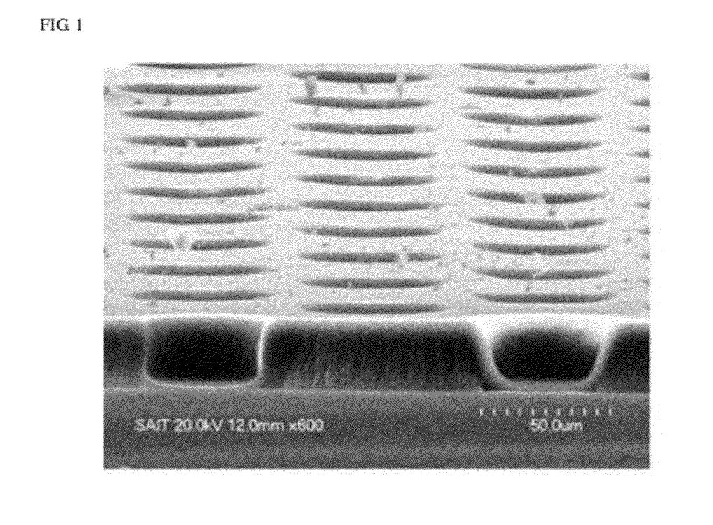

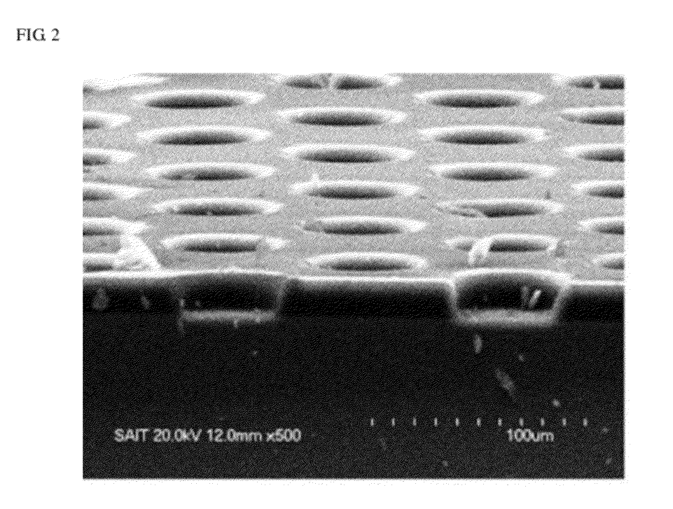

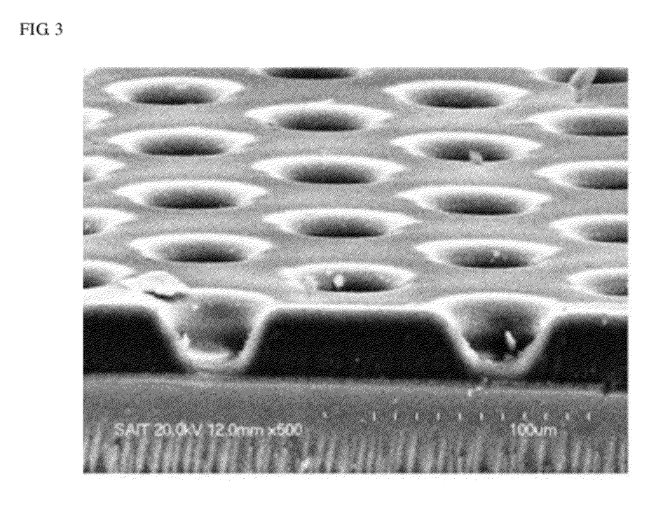

Patternability, curing rate, die shear strength, and storage stability of the adhesive films according to Examples 1 and 2 and Comparative Examples 1 and 2 are measured, and the results are shown in Table 2. Also, SEM images of patterned adhesive films are shown in FIGS. 1 to 3.

### Patternability

Each of the patternable adhesive films according to Examples 1 and 2 and Comparative Examples 1 and 2 are bonded on a wafer by a lamination process, exposed with light at an exposure dose of about 500 mJ/cm² by a high-precision parallel exposure system, developed for about 60 seconds using a 2.38% tetramethylammonium hydroxide (“TMAH”) solution, and then washed with deionized water (“DIW”) at a rotary rate of about 500 rpm for about 60 seconds. Thereafter, the resulting pattern is observed. The developability of the developed film laminated on the wafer is analyzed using a scanning electron microscopy (“SEM”). When a pattern is precisely formed, the result is designated as ⊚. When a pattern is sufficiently formed, the result is designated as ∘. When a pattern is insufficiently formed, the result is designated as Δ. Also, when no pattern is formed, the result is designated as x.

### Die Shear Strength

Each of the patternable adhesive films according to Examples 1 and 2 and Comparative Examples 1 and 2 is bonded on a 5 millimeter (mm)×5 mm silicon wafer, and exposed with light at an exposure dose of about 500 mJ/cm² by a high-precision exposure system, and developed and washed in the same method as above, thereby simulating a pattern forming process. The resulting pattern is bonded on a 10 mm×10 mm cut lower chip by a compressive bonding technique using a die bonder at a temperature of about 250° C. under a bonding pressure of about 1 kilograms-force (kgf) for about 5 seconds, and cured for about 2 hours at a temperature of about 175° C. The shear strength of an upper chip is measured using a die shear tester (DAGE 4000 from England) under test conditions of a temperature of about 250° C., a shear rate of about 100 micrometers per second (μm/sec), and a shear height of about 10 μm.

### Measurement of Curing Rate

A heat capacity value of each of the patternable adhesive films according to Examples 1 and 2 and Comparative Examples 1 and 2 is obtained using a differential scanning calorimeter (“DSC”). Afterwards, each of the adhesive films is bonded on a 5 mm×5 mm wafer, and exposed to light at an exposure dose of about 500 mJ/cm² by a high-precision parallel exposure system, and developed and washed using the same method as above, thereby simulating a pattern forming process. The resulting pattern is bonded on a 10 mm×10 mm cut lower chip by a compressive bonding technique using a die bonder at a temperature of about 250° C. under a bonding pressure of 1 about kgf for 5 about seconds. The shear strength of an upper chip is measured using a die shear tester (DAGE 4000 from England) under test conditions of a temperature of about 250° C., a shear rate of about 100 μm/sec, and a shear height of about 10 μm. Thereafter, the adhesive film remaining on the upper and lower chips is collected, and the heat capacity value of the remaining adhesive film is measured using a DSC. The curing rate is calculated by comparing the initial heat capacity value of the adhesive film with that of the remaining adhesive film obtained after the die shear test.

### Estimation of Storage Stability

Each of the patternable adhesive films according to Examples 1 and 2 and Comparative Examples 1 and 2 is stored under conditions of a temperature of about 30° C. and about 60% relative humidity (“RH”) for about 168 hours using a thermo-hygrostat. Thereafter, the die shear strength test is conducted.

TABLE 2

| | | | Comparative | Comparative |
|---|---|---|---|---|
| | Example 1 | Example 2 | Example 1 | Example 2 |
| Patternability | ⊚ | ⊚ | ◯ | Δ |
| Curing rate(%) | 90 | 90 | 60 | 50 |
| Shear strength (kgf) | 5 | 5.5 | 3 | 6 |
| Storage stability | ◯ | ◯ | ◯ | X |

As is disclosed in Table 2, the patternable adhesive films according to Examples 1 and 2 are rapidly curable and had much higher patternability, adhesiveness, and storage stability than the patternable adhesive films according to Comparative Examples 1 and 2.

The invention should not be construed as being limited to the embodiments set forth herein. Rather, these embodiments are provided so that this disclosure will be thorough and complete and will fully convey the disclosed embodiments to those of ordinary skill in the art.

While the invention has been particularly shown and described with reference to embodiments thereof, it will be understood by those of ordinary skill in the art that various changes in form and details may be made therein without departing from the spirit or scope of the present invention as defined by the following claims.

What is claimed is:

1. A composition for a patternable adhesive film, the composition comprising:
a binder resin,
a radical-polymerizable acrylate monomer,
a photo-radical initiator,
a thermal radical initiator, and
a solvent.

2. The composition of claim 1, wherein a content of the photo-radical initiator is from about 0.1 to 5 percent by weight, based on the total weight of the binder resin, the radical-polymerizable acrylate monomer, the photo-radical initiator, and the thermal radical initiator.

3. The composition of claim 1, wherein a thermal polymerization initiation temperature of the thermal radical initiator is from about 80 to about 150° C.

4. The composition of claim 1, wherein a content of the thermal-radical initiator is about 0.1 to about 5 percent by weight, based on the total weight of the binder resin, the radical-polymerizable acrylate monomer, the photo-radical initiator, and the thermal radical initiator.

5. The composition of claim 1, wherein a weight-average molecular weight of the radical-polymerizable acrylate monomer is about 100 to about 20000 grams per mole.

6. The composition of claim 1, wherein a content of the radical-polymerizable acrylate monomer is about 10 to about 80% by weight, based on the weight of the binder resin, the radical-polymerizable acrylate monomer, the photo-radical initiator, and the thermal radical initiator.

7. The composition of claim 1, wherein the binder resin comprises
a double bond, and
at least one selected from a carboxylic group, a hydroxyl group, and a phenolic group.

8. The composition of claim 1, wherein the binder resin comprises at least one selected from methyl(meth)acrylate, ethyl(meth)acrylate, butyl(meth)acrylate, isobutyl(meth)acrylate, 2-ethylhexyl(meth)acrylate, isooctyl(meth)acrylate, glycidyl(meth)acrylate, cyclohexyl(meth)acrylate, isobornyl(meth)acrylate, benzyl(meth)acrylate, 2-hydroxy(meth)acrylate, trimethoxybutyl(meth)acrylate, ethylcarbitol(meth)acrylate, phenoxyethyl(meth)acrylate, 2-hydroxyethyl(meth)acrylate, trimethylolpropane tri(meth)acrylate, tetramethylolmethane tetra(meth)acrylate, pentaerythritol hexa(meth)acrylate, pentaerythritol tetra(meth)acrylate, dipentadierythritolmonohydroxy penta(meth)acrylate, dipentaerythritol hexa(meth)acrylate, 1,4-butylglycol di(meth)acrylate, 1,6-hexanediol di(meth)acrylate, polyethyleneglycol di(meth)acrylate, oligoester (meth)acrylate, a multifunctional urethane (meth)acrylate, and urea (meth)acrylate.

9. The composition of claim 1, wherein the radical-polymerizable acrylate monomer comprises at least one selected from isobornyl(meth)acrylate, 1,6-hexanediol diacrylate, triethylene glycol diacrylate, trimethylolpropane triacrylate, tetraethylene glycol diacrylate, 1,3-butanediol diacrylate, neopentyl glycol diacrylate, pentaerythritol triacrylate, and dipentaerythritol hydroxypentacrylate.

10. The composition of claim 1, wherein the photo-radical initiator comprises at least one selected from 1-hydroxy-cyclohexyl-phenyl-ketone, 2-hydroxy-2-methyl-1-phenyl-1-propanone, 2-hydroxy-1-[4-(2-hydroxyethoxy)phenyl]-2-methyl-1-propanone, methyl benzoylformate, α,α-dimethoxy-α-phenylacetophenone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diphenyl (2,4,6-trimethylbenzoyl)-phosphine oxide, and phosphine oxide.

11. The composition of claim 1, wherein thermal radical initiator comprises at least one selected from ketone peroxide containing methyl isobutyl ketone, hydroperoxide containing tertiary butyl hydroperoxide, peroxyester, dialkyl peroxide, methoxybutyl peroxydicarbonate, di-(2,4-dichlorobenzoyl)-peroxide, dibenzoyl peroxide, t-butyl peroxybenzoate, 1,1-di-(t-butylperoxy)-3,3,5-trimethylcyclohexane, dicumyl peroxide, di-(2-t-butylperoxyisopropyl)benzene, t-butylcumylperoxide, di-t-butylperoxide, azobisisobutyronitrile, azobiscarbonamide, and azobisalkanonitrile.

12. The composition of claim 1, further comprising a silane coupling agent.

13. The composition of claim 1, which is cured at about 250° C. for less than about 10 seconds.

14. A patternable adhesive film, which comprises a product prepared by removing a solvent from the composition of claim 1.

15. A semiconductor package comprising:
a plurality of semiconductor chips; and
an adhesive layer,
wherein the adhesive layer is a product of removing a solvent from and curing the composition of claim 1.

16. A method of manufacturing a semiconductor package, the method comprising:
applying a composition on a surface of a semiconductor chip or on a surface of a substrate to form a patternable adhesive film, wherein the composition comprises
a binder resin,
a radical-polymerizable acrylate monomer,
a photo-radical initiator,
a thermal radical initiator, and
a solvent;
forming a predetermined pattern by exposing and developing the patternable adhesive film; and
forming an adhesive layer by a thermally curing the patternable adhesive film to form the semiconductor package.

17. A method of manufacturing a semiconductor package, the method comprising:
disposing a patternable adhesive film, wherein the adhesive film is prepared by removing a solvent from a composition comprising
a binder resin,
a radical-polymerizable acrylate monomer,
a photo-radical initiator,
a thermal radical initiator, and
a solvent;
forming a predetermined pattern by exposing and developing the patternable adhesive film; and
forming an adhesive layer by thermally curing the patternable adhesive film to form the semiconductor package.
